(19) United States
(12) Patent Application Publication
(10) Pub. No.: US 2006/0175610 A1
(43) Pub. Date: Aug. 10, 2006

(54) Signal line, thin film transistor array panel with the signal line, and method for manufacturing the same

(75) Inventors: Seong-Kweon Heo, Gyeonggi-do (KR); Hoon-Kee Min, Seoul (KR); In-Sung Lee, Seoul (KR); Sung-Su Hong, Seoul (KR); Ho-Min Kang, Gyeonggi-do (KR); Ki-Wan Ahn, Gyeonggi-do (KR)

Correspondence Address: David W. Heid;MacPHERSON KWOK CHEN & HEID LLP, Suite 226, 1762 Technology Drive, San Jose, CA, 95110, US

(73) Assignee: Samsung Electronics Co., Ltd.

(21) Appl. No.: 11/336,139

(22) Filed: Jan. 20, 2006

(30) Foreign Application Priority Data
Feb. 7, 2005 (KR) 10-2005-0011467

(51) Int. Cl. H01L 29/04

(52) U.S. Cl. 257/59

(57) ABSTRACT

System and techniques for providing signal lines comprising copper alloys including at least one of molybdenum, tungsten, and chromium. The present disclosure provides a thin film transistor array panel comprising an insulating substrate; a gate line formed on the insulating substrate; a gate insulating layer formed on the gate line; a semiconductor layer formed on the gate insulating layer; ohmic contacts formed on the gate insulating layer and the semiconductor layer; a data line having a source electrode formed on one of the ohmic contacts and having a narrower width than the ohmic contact thereunder; a drain electrode facing the source electrode with a gap therebetween and having a narrower width than the ohmic contact thereunder; and a pixel electrode connected to the drain electrode, wherein at least one of the gate line and the data line comprises a Cu-alloy that contains Cu and one selected from molybdenum (Mo), tungsten (W), and chromium (Cr).

### CROSS-REFERENCE TO RELATED APPLICATIONS

This application claims priority to Korean Patent Application No. 10-2005-0011467, filed in the Korean Patent Office on Feb. 7, 2005, the disclosure of which is hereby incorporated by reference in its entirety.

### BACKGROUND OF THE INVENTION

(a) Field of the Invention

The present description relates to signal lines, a thin film transistor (TFT) array panel for a liquid crystal display (LCD) or an organic light emitting display (OLED), and a manufacturing method for the same.

(b) Description of the Related Art

Liquid crystal displays (LCDs) are a widely used type of flat panel display. An LCD includes a liquid crystal (LC) layer interposed between two panels provided with field-generating electrodes. The LCD displays images by applying appropriate voltages to the field-generating electrodes to generate an electric field in the LC layer. The applied voltages determine the orientation of LC molecules in the LC layer to adjust polarization of incident light.

The LCD market is dominated by displays incorporating two panels, each of which is provided with field-generating electrodes. One of the two panels has a plurality of pixel electrodes in a matrix, while the other has a common electrode covering the entire surface of the panel.

An LCD displays images by applying a pixel voltage to each pixel electrode. For this purpose, thin film transistors (TFTs) having three terminals to switch voltages applied to the pixel electrodes are connected to the pixel electrodes. Gate lines to transmit signals for controlling the thin film transistors and data lines to transmit pixel voltages applied to the pixel electrodes are formed on a thin film transistor array panel.

A TFT is a switching element for transmitting image data signals from the data line to the appropriate pixel electrode in response to the scanning signals from the gate line.

In a an active matrix organic light emitting display, a TFT is may be used as a switching element for controlling respective light emitting elements.

Currently, chromium (Cr) is the primary material used for the gate lines and the data lines of a TFT array panel. However, because of its relatively high resistivity, chromium may not be optimal for larger displays, which have longer gate and data lines.

Copper (Cu) is a well known material that may be used as a substitute for Cr, due to its low resistivity. However, Cu has generally poor adhesiveness for a glass substrate, and diffuses relatively into other layers. Therefore, Cu may not be an optimal material for display gate lines and a data lines.

### SUMMARY OF THE INVENTION

Systems and techniques described herein may provide a signal line exhibiting both low resistivity and good reliability, as well as a thin film transistor array panel incorporating the signal line.

In general, in one aspect, the present disclosure provides a signal line comprising a copper (Cu)-alloy comprising Cu and at least one selected from among molybdenum (Mo), tungsten (W), and chromium (Cr).

In general, in another aspect, the present disclosure provides a thin film transistor array panel comprising an insulating substrate; a gate line formed on the insulating substrate; a data line intersecting the gate line; a thin film transistor connected to the gate line and the data line; and a pixel electrode connected to the thin film transistor, wherein at least one of the gate line and the data line comprises a Cu-alloy that includes Cu and at least one selected from among molybdenum (Mo), tungsten (W), and chromium (Cr).

In general, in another aspect, the present disclosure provides a thin film transistor array panel comprising an insulating substrate; a gate line formed on the insulating substrate; a gate insulating layer formed on the gate line; a semiconductor layer formed on the gate insulating layer; ohmic contacts formed on the gate insulating layer and the semiconductor layer; a data line having a source electrode formed on one of the ohmic contacts and having a narrower width than the ohmic contact thereunder; a drain electrode facing the source electrode with a gap therebetween and having a narrower width than the ohmic contact thereunder; and a pixel electrode connected to the drain electrode, wherein at least one of the gate line and the data line comprises a Cu-alloy that includes Cu and at least one selected from molybdenum (Mo), tungsten (W), and chromium (Cr).

In general, in another aspect, the present disclosure provides a manufacturing method of a thin film transistor array panel comprising: forming a gate line having a gate electrode on an insulating substrate; depositing a gate insulating layer, a semiconductor layer, and an ohmic contact layer on the gate line; patterning the ohmic contact layer and the semiconductor layer to form an ohmic contact pattern and a semiconductor pattern; depositing a Cu-alloy layer comprising Cu and at least one selected from among molybdenum (Mo), tungsten (W), and chromium (Cr); forming a photo resist pattern on the Cu-alloy layer; forming a drain electrode and a data line having a source electrode by etching the Cu-alloy layer using the photoresist pattern; etching the ohmic contact pattern using the photoresist pattern; and forming a pixel electrode connected to the drain electrode.

### BRIEF DESCRIPTION OF THE DRAWINGS

The above and other features and advantages of the present invention will become more apparent by describing in detailed embodiments thereof with reference to the accompanying drawings, in which:

FIG. 1 is a layout view of a TFT array panel for an LCD according to an embodiment of the present invention;

FIG. 2 is a sectional view of the TFT array panel shown in FIG. 1 taken along the line II-II;

FIGS. 3A, 4A, 5A, and 7A are layout views sequentially illustrating the intermediate steps of a method of manufacturing a TFT array panel for an LCD according to the embodiment of FIGS. 1 and 2;

FIG. 3B is a sectional view of the TFT array panel shown in FIG. 3A taken along the line IIIb-IIIb′;

FIG. 4B is a sectional view of the TFT array panel shown in FIG. 4A taken along the line IVb-IVb′ in the step following the step shown in FIG. 3B;

FIG. 5B is a sectional view of the TFT array panel shown in FIG. 5A taken along the line Vb-Vb′ in the step following the step shown in FIG. 4B;

FIG. 6 is a sectional view of the TFT array panel in the step following the step shown in FIG. 5B;

FIG. 7B is a sectional view of the TFT array panel shown in FIG. 7A taken along the line VIIb-VIIb′ in the step following the step shown in FIG. 6;

FIG. 8 is a layout view of a TFT array panel for an OLED according to another embodiment of the present invention;

FIGS. 9A and 9B are sectional views of the TFT array panel shown in FIG. 8 taken along the line IXa-IXa′ and the line IXb-IXb′, respectively;

FIGS. 10 to 24B are layout views or sectional views of the TFT array panel shown in FIGS. 8 to 9B in intermediate steps of a manufacturing method according to an embodiment of the present invention.

### DETAILED DESCRIPTION

Exemplary embodiments of the present invention will now be described more fully hereinafter with reference to the accompanying drawings, in which preferred embodiments of the invention are shown. The present invention may, however, be embodied in different forms and should not be construed as being limited to the embodiments set forth herein. Rather, these embodiments are provided so that this disclosure will be thorough and complete, and will fully describe the invention to those skilled in the art.

In the drawings, the thickness of layers, films, and regions are exaggerated for clarity. Like numerals refer to like elements throughout. It will be understood that when an element such as a layer, film, region, or substrate is referred to as being “on” another element, it can be directly on the other element or intervening elements may also be present.

In the following, embodiments of TFT array panels for LCD and OLED displays, as well as manufacturing methods thereof, will be described in detail with reference to the accompanying drawings.

### EMBODIMENT 1

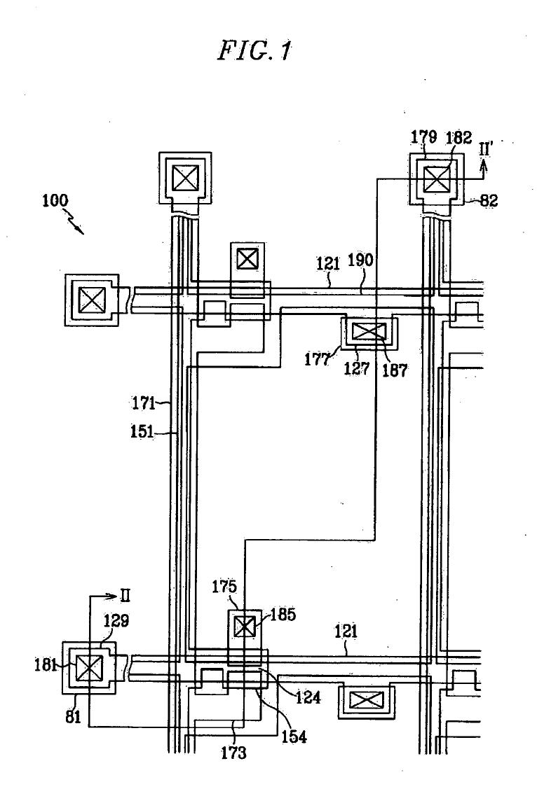

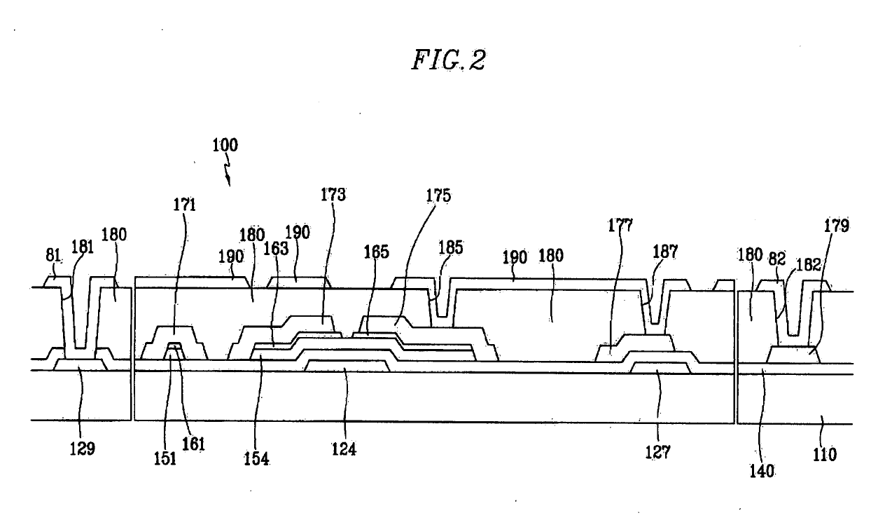

First, a TFT array panel for an LCD according to an embodiment of the present invention will be described in detail with reference to FIGS. 1 and 2.

FIG. 1 is a layout view of a TFT array panel 100 for an LCD according to an embodiment of the present invention. FIG. 2 is a sectional view of the TFT array panel 100 shown in FIG. 1 taken along the line II-II′.

A plurality of gate lines 121 for transmitting gate signals are formed on an insulating substrate 110. The gate lines 121 are mainly formed in the horizontal direction, and partial portions thereof become a plurality of gate electrodes 124. Also, different partial portions thereof that extend in a downward direction as a plurality of expansions 127. An end portion 129 of the gate line 121 has an expanded width for connecting to an external device such as driving circuit.

The gate line 121 comprises a Cu-alloy containing Cu as a main element and one selected from among molybdenum (Mo), tungsten (W), and chromium (Cr).

Since Cu is a low resistivity material, when Cu is used as a material for signal lines, problems associated with high resistance, such as signal delay, are reduced. However, since Cu adheres poorly to a glass substrate, a Cu signal line may be easily lifted or peeled. Furthermore, Cu is easily oxidized (which increases signal line resistance) and diffuses to other layers.

The systems and techniques herein provide for a signal line made of a copper (Cu)-alloy that contains Cu and at least one selected from among molybdenum (Mo), tungsten (W), and chromium (Cr). The resulting signal lines have low resistance, enhanced substrate adhesion, and reduced diffusion to lower and/or upper layers.

To obtain the above characteristics using a Cu-alloy, the minor component of the Cu-alloy, which is a metal such as Mo, W, and Cr, is preferably contained 0.1 to 3 wt % in the Cu-alloy. If the amount of the minor component falls below the lower boundary of 0.1 wt %, adhesion and diffusion properties of the resulting alloy may not be sufficient. If the amount of the minor component falls below the upper level of 3 wt %, the resistance may be higher than desired.

The Cu-ally may further contain at least one metal selected from aluminum (Al), gold (Au), nickel (Ni), cobalt (Co), silicon (Si), titanium (Ti), and tantalum (Ta). Here, it is preferable that the additional metal is contained 0.1 to 3.0 wt % in the Cu-alloy.

The lateral sides of the gate lines 121 are inclined relative to a surface of the substrate 110, and the inclination angle thereof ranges from about 30 degrees to about 80 degrees.

A gate insulating layer 140, preferably comprising silicon nitride (SiNx), is formed on the gate lines 121.

A plurality of semiconductor stripes 151, preferably comprising hydrogenated amorphous silicon (abbreviated as “a-Si”), are formed on the gate insulating layer 140. Each semiconductor stripe 151 extends substantially in the longitudinal direction (i.e., into the page in FIG. 2 and vertically in FIG. 1). Each semiconductor stripe 151 has a plurality of projections 154 branched out toward the gate electrodes 124. The width of each semiconductor stripe 151 becomes large near the gate lines 121 such that the semiconductor stripe 151 covers large areas of the gate lines 121.

A plurality of ohmic contact stripes 161 and islands 165, preferably comprising silicide or n+ hydrogenated a-Si heavily doped with n type impurity, are formed on the semiconductor stripes 151. Each ohmic contact stripe 161 has a plurality of projections 163, and the projections 163 and the ohmic contact islands 165 are located in pairs on the projections 154 of the semiconductor stripes 151.

The edge surfaces of the semiconductor stripes 151 and the ohmic contacts 161 and 165 are tapered, and the inclination angles of the edge surfaces of the semiconductor stripes 151 and the ohmic contacts 161 and 165 are preferably in a range from about 30 degrees to about 80 degrees.

A plurality of data lines 171, a plurality of drain electrodes 175, and a plurality of storage capacitor conductors 177 are formed on the ohmic contacts 161 and 165 and the gate insulating layer 140.

The data lines 171, for transmitting data voltages, extend substantially in the longitudinal direction and intersect the gate lines 121 to define pixel areas arranged in a matrix. Each data line 171 has a plurality of branches which project toward the drain electrodes 175. The branches form a plurality of source electrodes 173 and have end portions 179 having enlarged width. Each pair of the source electrodes 173 and the drain electrodes 175 are separated from each other at the gate electrodes 124, and oppose each other.

The data line 171, the drain electrode 175, and the storage capacitor conductor 177 are made of a Cu-alloy containing Cu as a main element and at least one selected from among molybdenum (Mo), tungsten (W), and chromium (Cr).

Since Cu has low resistivity, when Cu is applied as a material for signal lines, problems caused by high resistance (such as signal delay) are reduced. However, Cu is easily oxidized (which increases signal line resistance) and easily diffuses to other layer. For example, when the data line 171 is formed of Cu, Cu may diffuse to the lower semiconductor stripe 151 or upper layers.

To reduce oxidation and diffusion, the present disclosure provides a signal line made of a copper (Cu)-alloy that contains Cu and at least one selected from among molybdenum (Mo), tungsten (W), and chromium (Cr).

Signal lines incorporating a Cu-alloy have lower resistance, enhanced adhesion properties, and substantially reduced diffusion to lower and/or upper layers than those incorporating un-alloyed Cu.

To obtain the above-described benefits, the minor component of the Cu-alloy (which is a metal such as Mo, W, and Cr) is preferably contained 0.1 to 3 wt % in the Cu-alloy. Weight percentages less than the lower level of 0.1 wt % may not provide desired adhesion and diffusion reduction. Weight percentages greater than the upper level of 3 wt % may result in signal lines with greater resistance than desired.

The Cu-ally may further contain at least one metal selected from among aluminum (Al), gold (Au), nickel (Ni), cobalt (Co), silicon (Si), titanium (Ti), and tantalum (Ta). Here, it is preferable that the additional metal is contained 0.1 to 3.0 wt % in the Cu-alloy.

The data lines 171, the drain electrodes 175, and the storage capacitor conductor 177 have tapered edge surfaces, and the inclination angles of the edge surfaces are in a range from about 30 degrees to about 80 degrees.

A gate electrode 124, a source electrode 173, and a drain electrode 175, along with a projection 154 of a semiconductor stripe 151, form a TFT having a channel formed in the projection 154 disposed between the source electrode 173 and the drain electrode 175. The storage capacitor conductor 177 is overlapped with the expansion 127 of the gate line 121.

The ohmic contacts 161 and 165 are interposed between the semiconductor stripe 151 and the data line 171 and between the drain electrode 175 and the projection 154 of the semiconductor stripe 151, in order to reduce contact resistance therebetween. The ohmic contacts 161 and 165 have greater width than the source electrode 173 and the drain electrode 175 at their lower position. Accordingly, as shown in FIG. 2, the ohmic contacts 161 and 165 have an exposed portion not underlying the source electrode 173 and the drain electrode 175 on the channel region.

The semiconductor stripe 151 is partially exposed at the place between the source electrode 173 and the drain electrode 175 and at the other places not covered with the data line 171 and the drain electrode 175. Most of the semiconductor stripe 151 is narrower than the data line 171, but the width of the semiconductor stripe 151 broadens near a place where the semiconductor stripe 151 and the gate line 121 meet each other in order to prevent disconnection of the data line 171.

A passivation layer 180 is provided on the data line 171, the drain electrode 175, the storage capacitor conductor 177, and the exposed region of the semiconductor stripe 151. In some embodiments, passivation layer 180 comprises a substantially planar photosensitive organic material, while in some embodiments passivation layer 180 comprises an insulating material with a low dielectric constant such as a-Si:C:O, a Si:O:F, etc. In some embodiments, passivation layer 180 is formed by plasma enhanced chemical vapor deposition (PECVD). To prevent the organic material of the passivation layer 180 from contacting with the semiconductor strips 151 exposed between the data line 171 and the drain electrode 175, the passivation layer 180 can be structured such that an insulating layer (e.g., comprising SiNx or SiO₂) is formed under the organic material layer.

In the passivation layer 180, a plurality of contact holes 181, 185, 187, and 182 are formed to expose an end portion 129 of the gate line 121, the drain electrode 175, the storage capacitor conductor 177, and an end portion 179 of the data line 171 respectively.

A plurality of pixel electrodes 190 and a plurality of contact assistants 81 and 82, which may comprise IZO or ITO, are formed on the passivation layer 180.

Since the pixel electrode 190 is physically and electrically connected with the drain electrode 175 and the storage capacitor conductor 177 through the contact holes 185 and 187, respectively, the pixel electrode 190 receives the data voltage from the drain electrodes 175 and transmits it to the storage capacitor conductor 177.

When a data voltage is applied to the pixel electrode 190, an electric field is generated between the pixel electrode 190 and a common electrode (not illustrated) of the opposite panel (not illustrated) to which a common voltage is applied. As a result, the liquid crystal molecules in the liquid crystal layer are rearranged.

Also, as mentioned in the above, the pixel electrode 190 and the common electrode form a capacitor to store and preserve the received voltage after the TFT is turned off. This capacitor will be referred to as a “liquid crystal capacitor.” To enhance the voltage storage ability, another capacitor may be provided, which is connected in parallel to the liquid crystal capacitor and will be referred to as a “storage capacitor.” The storage capacitor is formed at an overlapping portion of the pixel electrode 190 and the adjacent gate line 121, which will be referred to as the “previous gate line.” In some embodiments, expansion 127 of the gate line 121 is provided to ensure the largest possible overlap dimension and thus to increase storage capacity of the storage capacitor. The storage capacitor conductor 177 is connected to the pixel electrode 190 and is overlapped with the expansion 127, and is provided at the bottom of the passivation layer 180 so that the pixel electrode 190 becomes close to the previous gate line 121.

When the passivation layer 180 is formed of a organic material having low dielectric constant, the pixel electrode 190 may be formed to at least partially overlap the gate line 121 and the data line 171.

The contact assistant 81 is connected to the end portion 129 of the gate line 121, while contact assistant 82 is connected to the end portions 179 of data line 171. The contact assistant 81 enhances adhesion between the end portion 129 of gate line 121 and one or more external devices (such as the driving integrated circuit), while contact assistant 82 enhances adhesion between the end portion 179 of the data line 171 and the external devices. Contact assistants 81 and 82 may also protect the external devices. Applying the contact assistants 81 and 82 is optional.

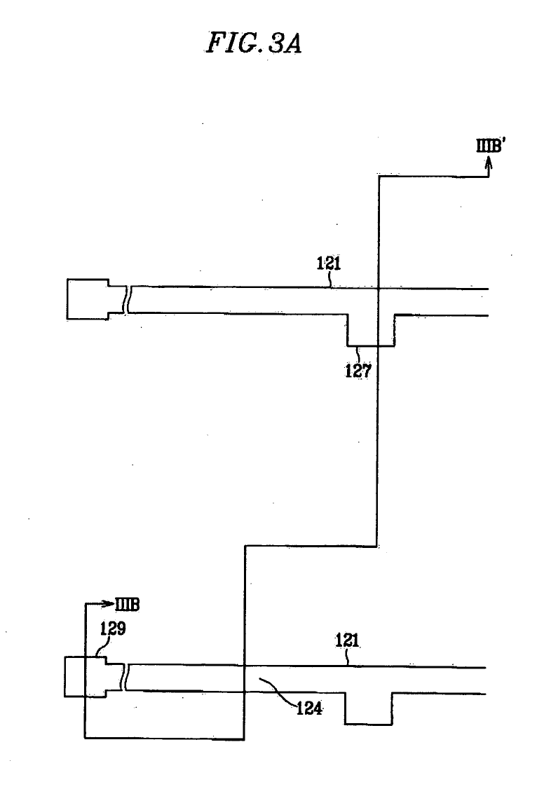

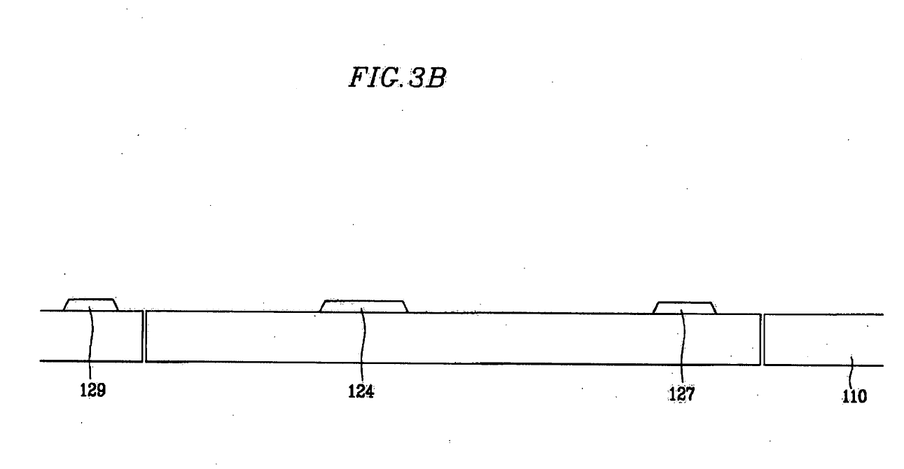

A method of manufacturing a TFT array panel will be described in detail with reference to FIGS. 3A to 7B as well as FIGS. 1 and 2.

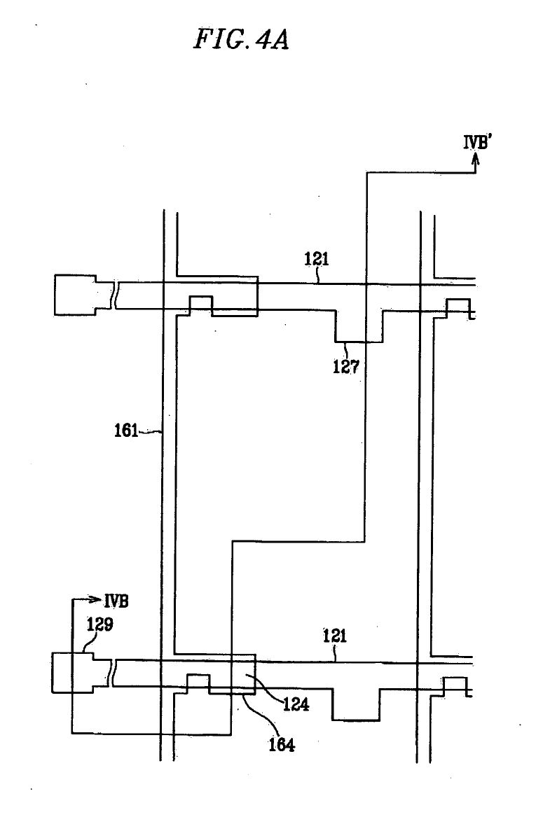

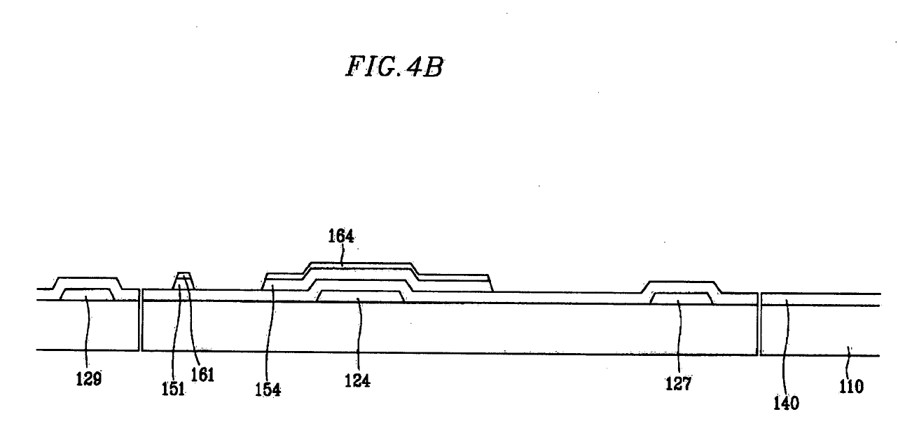

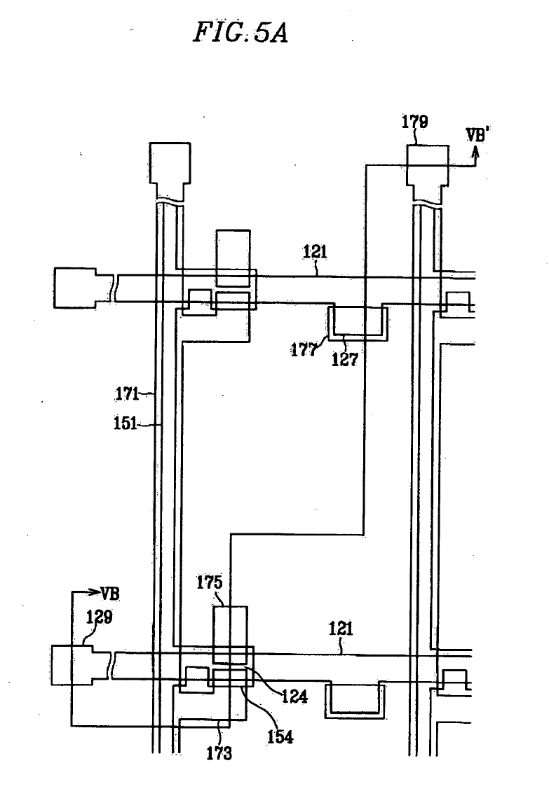

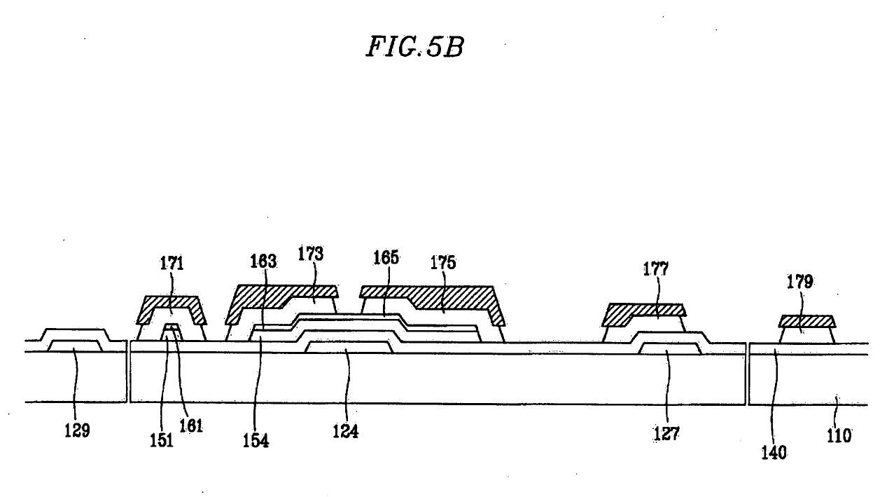

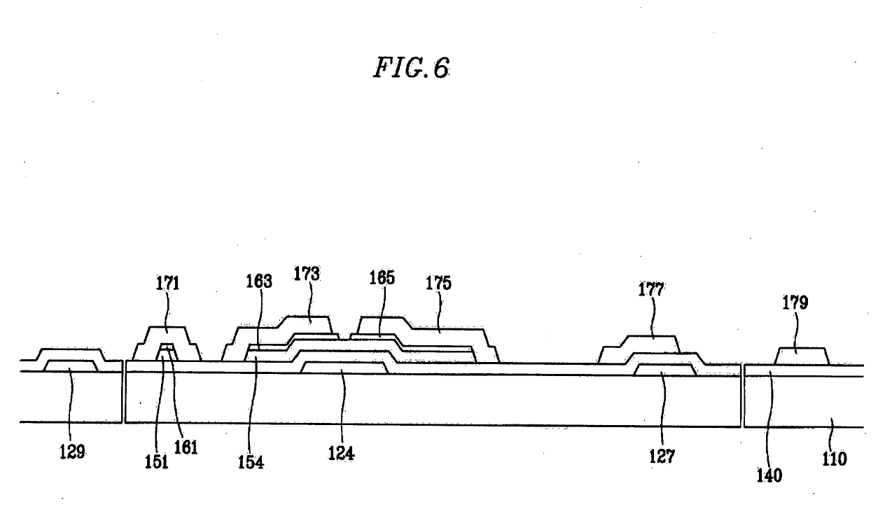

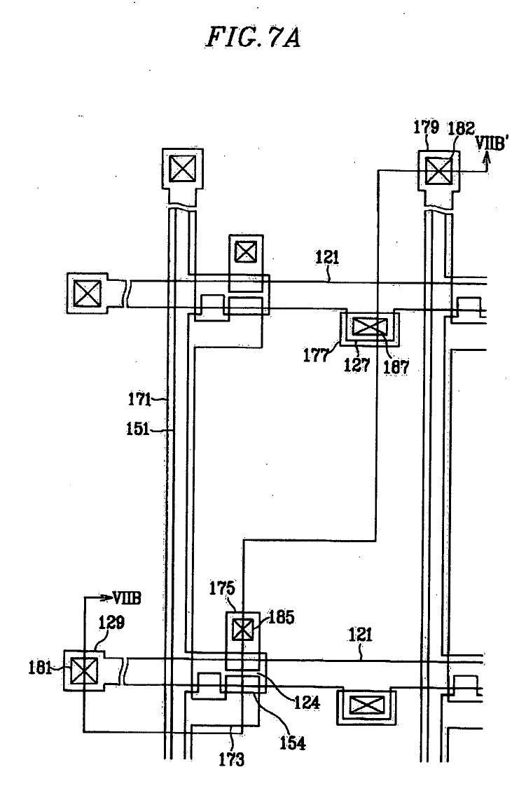

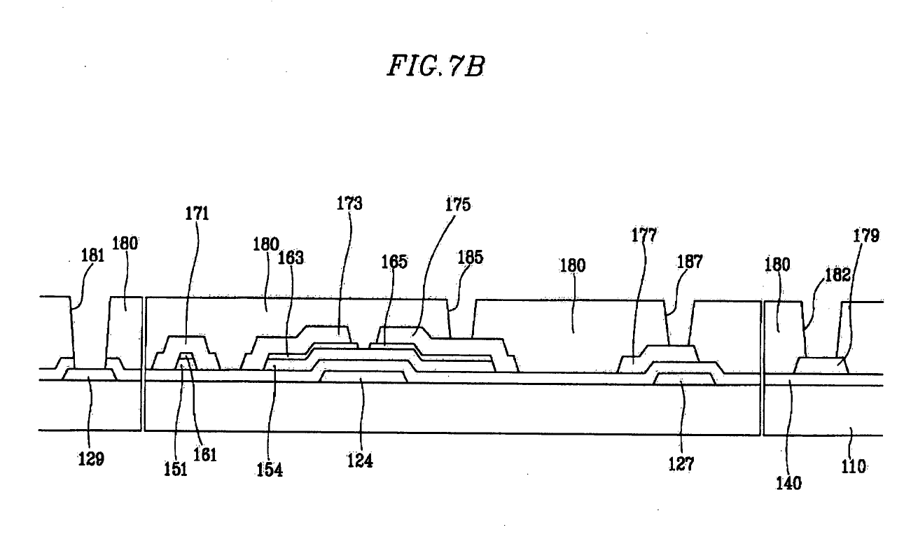

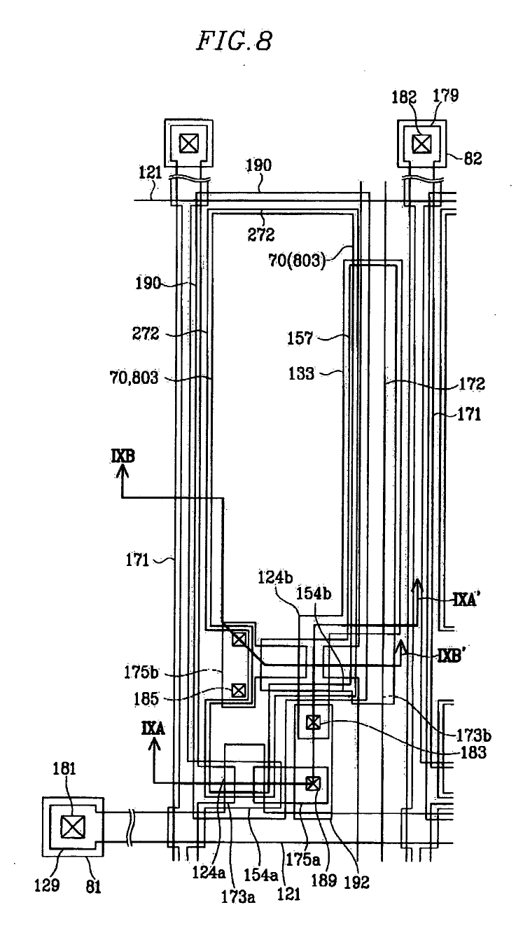

FIGS. 3A, 4A, 5A, and 7A are layout views sequentially illustrating the intermediate steps of a method of manufacturing a TFT array panel for a display device such as an LCD according to the embodiment of FIGS. 1 and 2. FIG. 3B is a sectional view of the TFT array panel shown in FIG. 3A taken along the line IIIb-IIIb′. FIG. 4B is a sectional view of the TFT array panel shown in FIG. 4A taken along the line IVb-IVb′ in the step following the step shown in FIG. 3B. FIG. 5B is a sectional view of the TFT array panel shown in FIG. 5A taken along the line Vb-Vb′ in the step following the step shown in FIG. 4B. FIG. 6 is a sectional view of the TFT array panel in the step following the step shown in FIG. 5B. FIG. 7B is a sectional view of the TFT array panel shown in FIG. 7A taken along the line VIIb-VIIb′ in the step following the step shown in FIG. 6.

At first, as shown in FIGS. 3A and 3B, a Cu-alloy layer is formed on an insulating substrate 110, and then processed to form a plurality of gate lines 121 having a plurality of gate electrodes 124, expansions 127, and end portions 129.

The Cu-alloy layer contains Cu as a main element and one or more selected from among molybdenum (Mo), tungsten (W), and chromium (Cr). The minor component of the Cu-alloy, which is a metal comprising Mo, W, and Cr, and/or other appropriate metal, is preferably contained 0.1 to 3 wt % in the Cu-alloy layer.

The Cu-alloy layer may further contain at least one metal selected from aluminum (Al), gold (Au), nickel (Ni), cobalt (Co), silicon (Si), titanium (Ti), and tantalum (Ta). These additional metals are preferably contained 0.1 to 3 wt % in the Cu-alloy layer.

After forming the Cu-alloy layer on substrate 110, it is processed to form the desired structures. For example, the Cu-alloy layer is photo-etched using an appropriate etchant to form a plurality of gate lines 121. In some embodiments, the etchant may be one of hydrogen peroxide (H₂O₂) or a common etchant containing 50 to 80 wt % of phosphoric acid (H₂PO₃), 2 to 10 wt % of nitric acid (HNO₃), 2 to 15 wt % of acetic acid (CH₃COOH), and deionized water for the residue.

Using the above described processes, a plurality of gate lines 121 having a plurality of gate electrode 124, expansions 127, and end portions 129 are formed.

Referring to FIGS. 4A and 4B, after sequential deposition of a gate insulating layer 140, an intrinsic a-Si layer, and an extrinsic a-Si layer, the extrinsic a-Si layer and the intrinsic a-Si layer are photo-etched to form a plurality of extrinsic semiconductor stripes 161 and a plurality of intrinsic semiconductor stripes 151. Extrinsic semiconductor stripes 161 have projections 164, while intrinsic semiconductor stripes 151 have projections 154. The gate insulating layer 140 preferably comprises silicon nitride with a thickness of about 2,000 Å to about 5,000 Å, and the deposition temperature is preferably in a range between about 250° C. and about 500° C.

Next, referring to FIGS. 5A and 5B, a Cu-alloy layer is formed on the extrinsic semiconductor stripes 161. The Cu-alloy layer contains Cu as a main element and at least one selected from among molybdenum (Mo), tungsten (W), and chromium (Cr). The Cu-alloy layer is preferably formed to have thickness of about 3,000 Å, and the deposition temperature is preferably at about 150° C.

Then, photoresist is coated on the Cu-alloy layer and is illuminated with a light through a photo-mask. Next, the illuminated photoresist is developed to form a photoresist pattern.

Using the photoresist pattern, the Cu-alloy layer is etched with an etchant to form a plurality of data lines 171, drain electrodes 175, and storage capacitor conductor 177. In some embodiments, the etchant may be one of hydrogen peroxide (H₂O₂) or a common etchant containing 50 to 80 wt % of phosphoric acid (H₂PO₃), 2 to 10 wt % of nitric acid (HNO₃), 2 to 15 wt % of acetic acid (CH₃COOH), and deionized water for the residue.

Using the above described processes, a plurality of data lines 171 having a plurality of source electrode 173, a plurality of drain electrodes 175, an end portion 179, and storage capacitor conductors 177 are formed.

Next, without removing the photoresist pattern, portions of the extrinsic semiconductor stripes 161 not covered with the photoresist pattern are removed by dry etching, to complete a plurality of ohmic contacts 163 and 165 and to expose portions of the intrinsic semiconductor stripes 151.

Since the extrinsic semiconductor stripes 161 are dry-etched using the photoresist pattern that was formed for the data lines 171, the ohmic contacts 161 and 165 have exposed portions outside of the data lines 171 and the drain electrodes 175. Furthermore, since the data lines 171 and the drain electrodes 175 are covered by the photoresist pattern while etching the extrinsic semiconductor stripes 161, the data lines 171 and the drain electrodes 175 (which comprise a Cu-alloy) do not contact the etching gas such as chlorine gas (Cl₂).

Through the above described processes, referring to FIG. 6, the ohmic contact stripes 161 having protrusions 163 and the ohmic contact islands 165 are completed. Oxygen plasma treatment may follow thereafter in order to stabilize the exposed surfaces of the semiconductor stripes 151.

Referring to FIGS. 7A and 7B, a passivation layer 180 is deposited and dry etched along with the gate insulating layer 140 to form a plurality of contact holes 181, 185, 187, and 182. The dry etching is performed with a fluorine based gas (such as CF₄ or SF₆) and nitrogen gas (N₂) to avoid oxidation of the Cu-alloy by oxygen gas (O₂)

In some embodiments, the passivation layer may comprise a photosensitive material, and the contact holes may be formed by photolithography.

Next, referring to FIGS. 1 and 2, an indium tin oxide (ITO) layer is deposited on the passivation layer 180 to have a thickness about 400 to 1500□ and is patterned to form a plurality of pixel electrodes 190 and contact assistants 81 and 82.

### EMBODIMENT 2

A TFT panel for an active matrix organic light emitting display (AM-OLED) according to another embodiment of the present invention will be described.

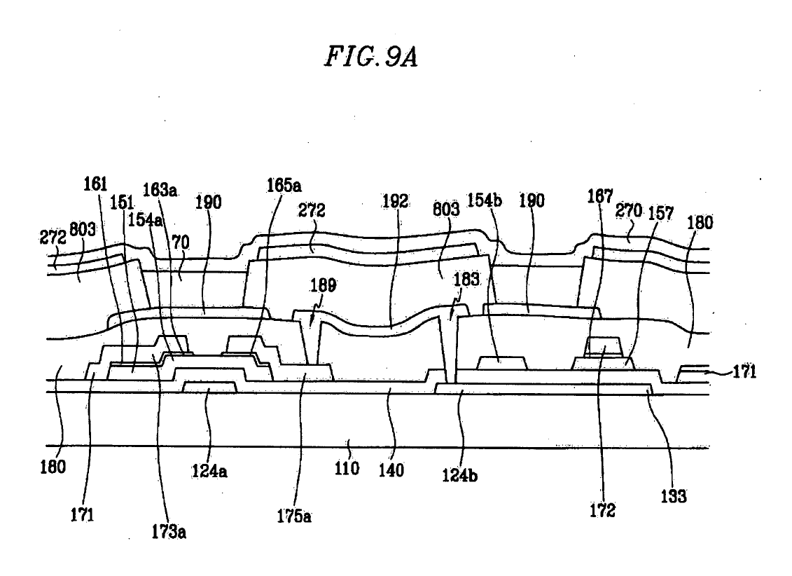

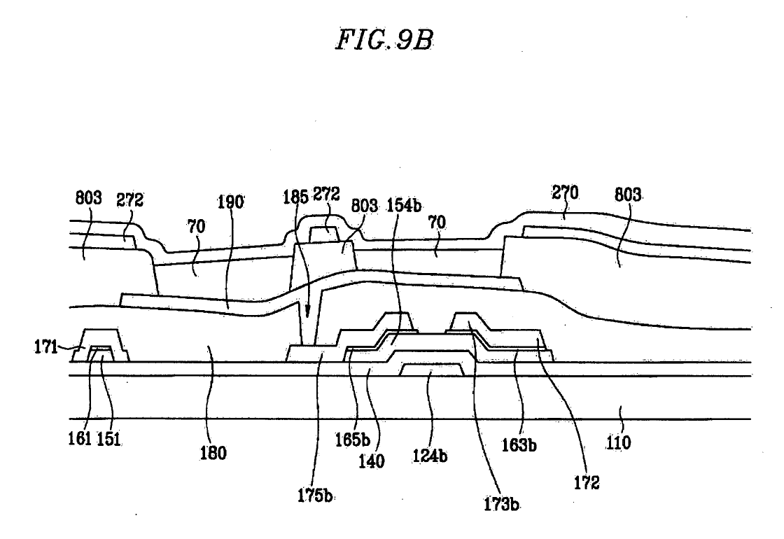

FIG. 8 is a layout view of a TFT array panel for an OLED according to another embodiment of the present invention. FIGS. 9A and 9B are sectional views of the TFT array panel shown in FIG. 8 taken along the line IXa-IXa′ and the line IXb-IXb′, respectively.

A plurality of gate conductors that include a plurality of gate lines 121. Gate lines 121 include a plurality of first gate electrodes 124a and a plurality of second gate electrodes 124b, and are formed on an insulating substrate 110 such as transparent glass.

The gate lines 121 transmitting gate signals extend substantially in a transverse direction (i.e. horizontally in FIG. 8) and are separated from each other. The first gate electrodes 124a protrude upward. The gate lines 121 may extend to be connected to a driving circuit (not shown) integrated on the substrate 110, or may have an end portion (not shown) having a large area for connection with another layer, an external driving circuit mounted on the substrate 110, or on another device such as a flexible printed circuit film (not shown) that may be attached to the substrate 110.

Each of the second gate electrodes 124b is separated from the gate lines 121 and includes a storage electrode 133 extending substantially in a transverse direction between two adjacent gate lines 121.

The gate lines 121, the first and second gate electrodes 124a and 124b and the storage electrodes 133 are made of a Cu-alloy containing Cu as a main element and at least one selected from among molybdenum (Mo), tungsten (W), and chromium (Cr).

Since Cu has low resistivity, when Cu is applied as a material for signal lines problems associated with high resistance, such as signal delay, are reduced. However, since Cu has poor adhesion property with a glass substrate, the resulting signal line may be easily lifted or peeled from the substrate. Furthermore, Cu is easily oxidized (which increases signal line resistance), and easily diffuses into other layers.

The present disclosure provides a signal line made of a copper (Cu)-alloy that contains Cu and at least one selected from among molybdenum (Mo), tungsten (W), and chromium (Cr). The resulting signal line has improved resistance, substrate adhesion, and diffusion characteristics.

To obtain the above characteristics using a Cu-alloy, the minor component of the Cu-alloy, which is a metal such as Mo, W, and Cr, is preferably contained 0.1 to 3 wt % in the Cu-alloy. If the amount of the minor component falls below the lower boundary of 0.1 wt %, adhesion and diffusion properties of the resulting alloy may not be sufficient. If the amount of the minor component falls below the upper level of 3 wt %, the resistance may be higher than desired.

The Cu-ally may further contain at least one metal selected from among Al, Au, Ag, Ni, Co, Si, Ti, and Ta. Here, it is preferable that the additional metal is contained 0.1 to 3.0 wt % in the Cu-alloy.

In addition, the lateral sides of the gate conductors 121, 124b, and 133 are inclined relative to a surface of the substrate 110, and the inclination angle thereof ranges from about 30 degrees to about 80 degrees.

A gate insulating layer 140, preferably comprising silicon nitride (SiNx), is formed on the gate conductors 121, 124b, and 133.

A plurality of semiconductor stripes 151 and islands 154b, preferably comprising hydrogenated amorphous silicon (abbreviated to “a-Si”) or polysilicon, are formed on the gate insulating layer 140. Each semiconductor stripe 151 extends substantially in the longitudinal direction and has a plurality of projections 154a branched out toward the first gate electrodes 124a. Each semiconductor island 154b crosses a second gate electrode 124b and includes a portion 157 overlapping the storage electrode 133 of the second gate electrode 124b.

A plurality of ohmic contact stripes 161 and ohmic contact islands 163b, 165a, and 165b, which preferably comprise silicide or n+ hydrogenated a-Si heavily doped with n type impurity such as phosphorous, are formed on the semiconductor stripes 151 and islands 154b. Each ohmic contact stripe 161 has a plurality of projections 163a, and the projections 163a and the ohmic contact islands 165a are located in pairs on the projections 154a of the semiconductor stripes 151. The ohmic contact islands 163b and 165b are located in pairs on the semiconductor islands 154b.

The lateral sides of the semiconductor stripes 151 and islands 154b and the ohmic contacts 161, 163b, 165b, and 165b are inclined relative to a surface of the substrate, and the inclination angles thereof are preferably in a range from about 30 degrees to about 80 degrees.

A plurality of data conductors including a plurality of data lines 171, a plurality of voltage transmission lines 172, and a plurality of first and second drain electrodes 175a and 175b are formed on the ohmic contacts 161, 163b, 165b, and 165b and the gate insulating layer 140.

The data lines 171 for transmitting data signals extend substantially in the longitudinal direction and intersect the gate lines 121. Each data line 171 includes a plurality of first source electrodes 173a and an end portion having a large area for contact with another layer or an external device. In some embodiments, the data lines 171 may be directly connected to a data driving circuit for generating the gate signals, which may be integrated on the substrate 110.

The voltage transmission lines 172 for transmitting driving voltages extend substantially in the longitudinal direction and intersect the gate lines 121. Each voltage transmission line 172 includes a plurality of second source electrodes 173b. The voltage transmission lines 172 may be connected to each other. The voltage transmission lines 172 overlap the storage region 157 of the semiconductor islands 154b.

The first and the second drain electrodes 175a and 175b are separated from the data lines 171 and the voltage transmission lines 172, and from each other. Each pair of the first source electrodes 173a and the first drain electrodes 175a are disposed opposite each other with respect to a first gate electrode 124a, and each pair of the second source electrodes 173b and the second drain electrodes 175b are disposed opposite each other with respect to a second gate electrode 124b.

A first gate electrode 124a, a first source electrode 173a, and a first drain electrode 175a, along with a projection 154a of a semiconductor stripe 151 form a switching TFT having a channel formed in the projection 154a disposed between the first source electrode 173a and the first drain electrode 175a. Meanwhile, a second gate electrode 124b, a second source electrode 173b, and a second drain electrode 175b, along with a semiconductor island 154b form a driving TFT having a channel formed in the semiconductor island 154b disposed between the second source electrode 173b and the second drain electrode 175b.

The data conductors 171, 172, 175a, and 175b comprise a Cu-alloy containing Cu as a main element and at least one selected from among molybdenum (Mo), tungsten (W), and chromium (Cr).

Since Cu has low resistivity, when Cu is applied as a material for signal lines, problems caused by high resistance (such as signal delay) are reduced. However, Cu is easily oxidized (which increases signal line resistance) and easily diffuses to other layer. For example, when the data line 171 is formed of Cu, Cu may diffuse to the lower semiconductor stripe 151 or upper layers.

To reduce resistance, oxidationn and diffusion, the present disclosure provides a signal line comprising a copper (Cu)-alloy that contains Cu and at least one selected from among molybdenum (Mo), tungsten (W), and chromium (Cr).

Signal lines incorporating a Cu-alloy have lower resistance, enhanced adhesion properties, and substantially reduced diffusion to lower and/or upper layers than those incorporating un-alloyed Cu.

To obtain the above-described benefits, the minor component of the Cu-alloy, (which is a metal such as Mo, W, and Cr), is preferably contained 0.1 to 3 wt % in the Cu-alloy. Weight percentages less than the lower level of 0.1 wt % may not provide desired adhesion and diffusion reduction. Weight percentages greater than the upper level of 3 wt % may result in signal lines with greater resistance than desired.

The Cu-ally may further contain at least one metal selected from among Al, Au, Ag, Ni, Co, Si, Ti, and Ta. Here, it is preferable that the additional metal is contained 0.1 to 3.0 wt % in the Cu-alloy.

Like the gate conductors 121 and 124b, the data conductors 171, 172, 175a, and 175b have tapered lateral sides relative to the surface of the substrate 110, and the inclination angles thereof range from about 30 degrees to about 80 degrees.

The ohmic contacts 161, 163b, 165b, and 165b are interposed only between the underlying semiconductor stripes 151 and islands 154b and the overlying data conductors 171, 172, 175a, and 175b thereon, and reduce the contact resistance therebetween.

The ohmic contacts 163a and 165a have greater width than the first source electrode 173a and the first drain electrode 175a at their lower position. The ohmic contacts 163b and 165b have greater width than the second source electrode 173b and the second drain electrode 175b at their lower position. Accordingly, as shown in FIGS. 9A and 9B, the ohmic contacts 163a, 165a, 163b, and 165b have an exposed portion not underlying the source electrodes 173a and 173b and the drain electrodes 175a and 175b on the channel region.

The semiconductor stripes 151 include a plurality of exposed portions that are not covered by the data conductors 171, 172, 175a, and 175b.

Most of the semiconductor stripe 151 is narrower than the data line 171, but the width of the semiconductor stripe 151 broadens near a place where the semiconductor stripe 151 and the gate line 121 come together, in order to prevent disconnection of the data line 171, as described above.

A passivation layer 180 is provided on the data conductors 171, 172, 175a, and 175b and the exposed portions of the semiconductor stripes 151 and islands 154b. In some embodiments, the passivation layer 180 preferably comprises an inorganic material, such as silicon nitride or silicon oxide, a photosensitive organic material having good flatness characteristics, or a low dielectric insulating material having a dielectric constant lower than 4.0, such as a-Si:C:O and a-Si:O:F, which may be formed by plasma enhanced chemical vapor deposition (PECVD). The passivation layer 180 may include a lower film of inorganic insulator and an upper film of organic insulator.

The passivation layer 180 has a plurality of contact holes 189, 183, 185, 181, and 182 exposing portions of the first drain electrode 175a, a second gate electrode 124b, the second drain electrode 175b, and the end portions 129 and 179 of the gate line 121 and the data line 171, respectively.

The contact holes 181 and 182 expose the end portions 129 and 179 of the gate line 121 and the data line 171 to connect them with external driving circuits. Anisotropic conductive films may be disposed between the output terminals of the external driving circuit and the end portions 129 and 175 to enhance electrical connection and physical adhesion. However, when driving circuits are directly fabricated on the substrate 110, contact holes are not formed. When gate driving circuits are directly fabricated on the substrate 110 and data driving circuits are formed as separate chips, only contact hole 181 exposing the end portion 179 of the data line 171 is formed.

A plurality of pixel electrodes 190, a plurality of connecting members 192, and a plurality of contact assistants 81 and 82 are formed on the passivation layer 180.

The pixel electrodes 190 are connected to the second drain electrodes 175b through the contact holes 185. The connecting member 192 connects the first drain electrode 175a and the second gate electrode 124b through the contact holes 189 and 183. The contact assistants 81 and 82 are connected to the end portions 129 and 179 of the gate line 121 and the data line 171 through the contact holes 181 and 182, respectively.

The pixel electrode 190, the connecting member 192, and the contact assistants 81 and 82 comprise a transparent conductor such as ITO or IZO.

A partition 803, an auxiliary electrode 272, a plurality of light emitting members 70, and a common electrode 270 are formed on the passivation layer 180, and the pixel electrodes 190.

The partition 803 comprises an organic or inorganic insulating material and forms frames of organic light emitting cells. The partition 803 is formed along boundaries of the pixel electrodes 190 and defines a space for filling with an organic light emitting material.

The light emitting member 70 is disposed on the pixel electrode 190 and surrounded by the partition 803. The light emitting member 70 comprises one light emitting material that emits red, green, or blue light. Red, green, and blue light emitting members 70 are disposed in a repeating sequence.

A hole injection layer (not illustrated) may be interposed between the pixel electrode 190 and the light emitting member 70. The hole injection layer may comprise poly(3,4-ethylene dioxy thiophene)-poly(styrene sulphone acid)(PEDOT/PSS).

The auxiliary electrode 272 has substantially the same planar pattern as the partition 803. The auxiliary electrode 272 contacts with the common electrode 270 to reduce resistance of the common electrode 270.

The common electrode 270 is formed on the partition 803, the auxiliary electrode 272, and the light emitting member 70. The common electrode 270 comprises a metal such as Al, which has low resistivity. The embodiment of FIGS. 9A and 9B illustrates a back emitting OLED. However, a front emitting OLED or dual-emitting OLED may be used. For a front emitting or dual-emitting OLED, the common electrode 270 comprises a transparent conductor such as ITO or IZO.

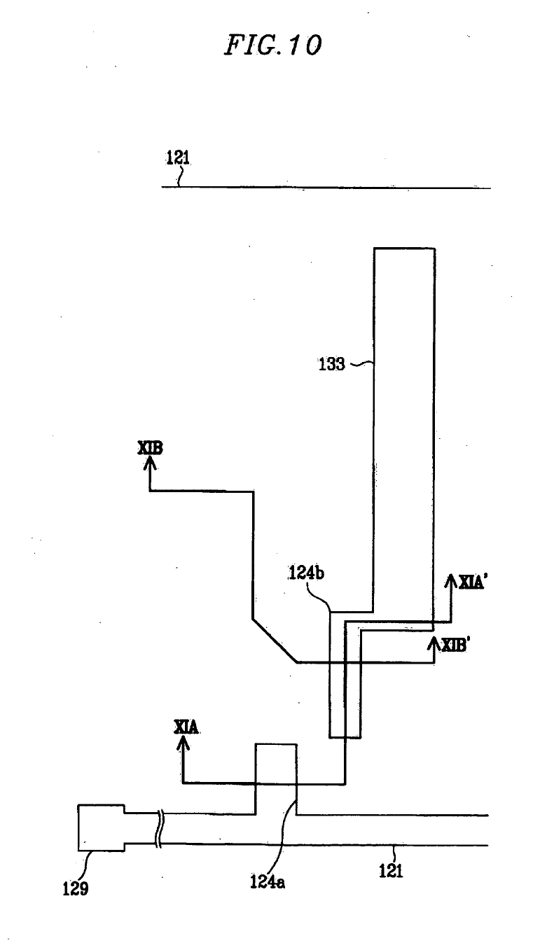

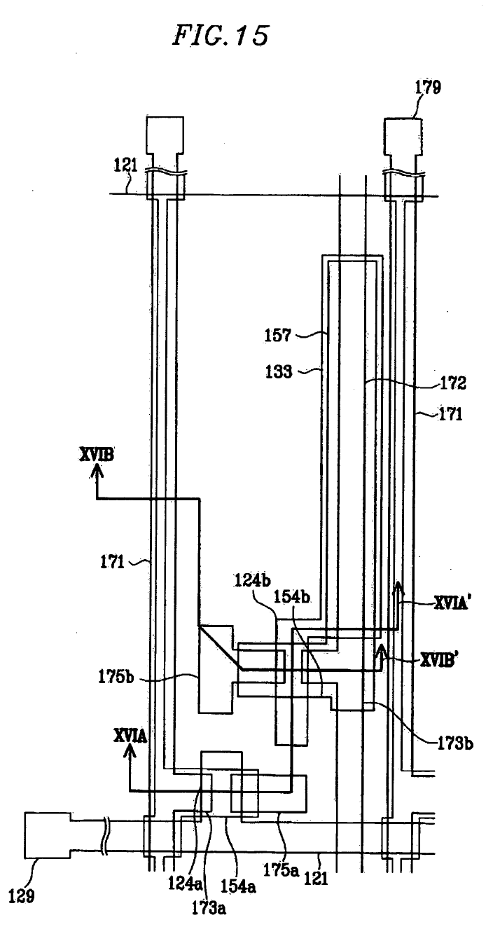

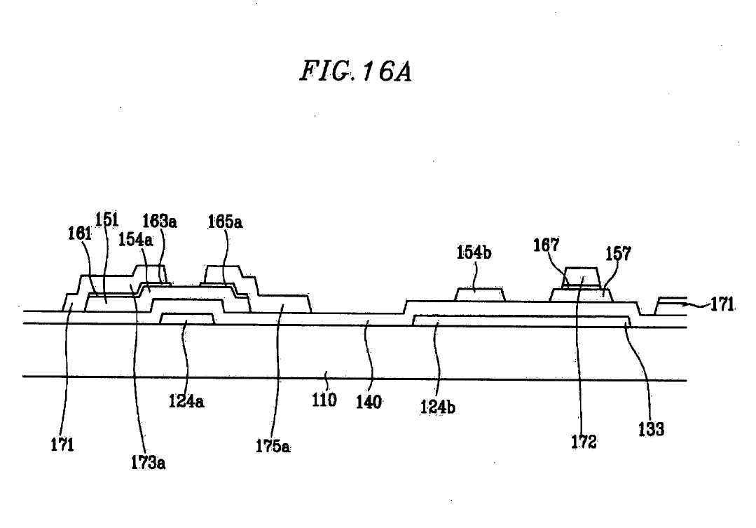

A method of manufacturing the TFT array panel shown in FIGS. 8 to 9B according to an embodiment of the present invention will be now described in detail with reference to FIGS. 10 to 24B as well as FIGS. 8 to 9B.

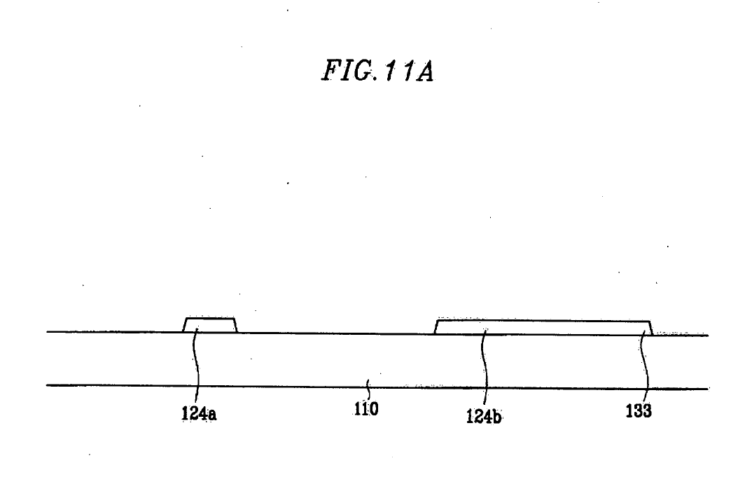

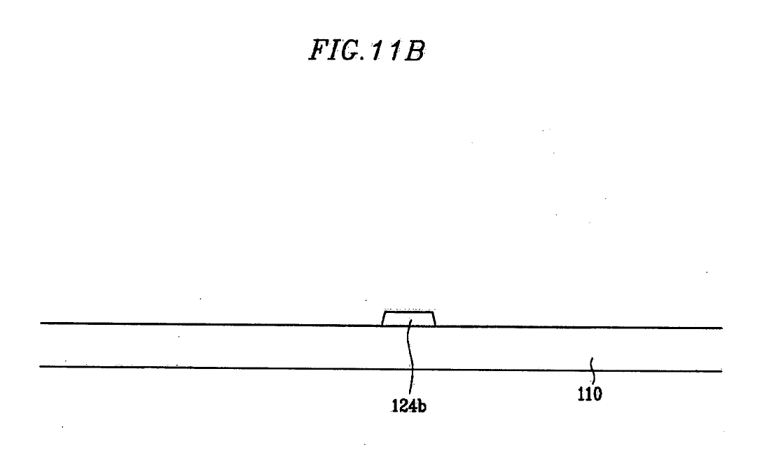

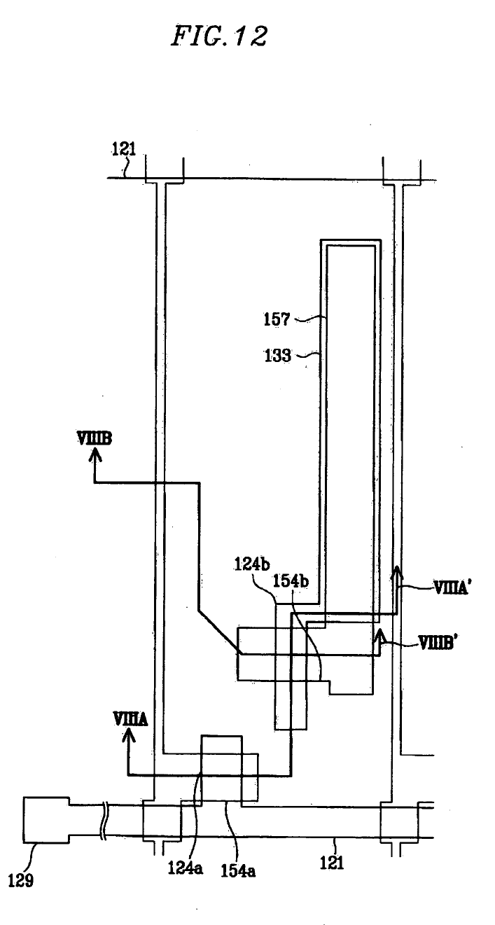

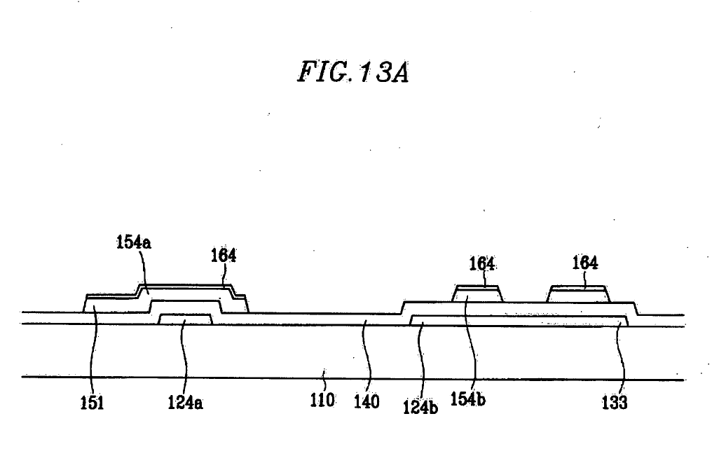

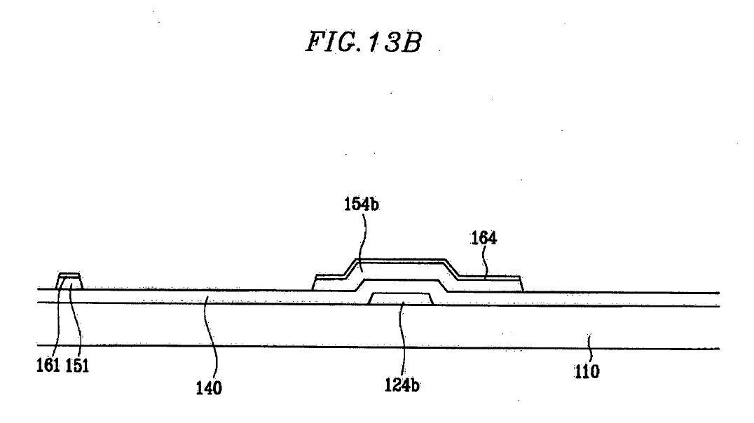

First, as shown in FIGS. 10 and 11B, a Cu-alloy layer is formed on an insulating substrate 110.

The Cu-alloy layer contains Cu as a main element and at least one selected from among molybdenum (Mo), tungsten (W), and chromium (Cr). The minor component of the Cu-alloy, which is a metal such as Mo, W, and Cr, is preferably contained 0.1 to 3 wt % in the Cu-alloy layer.

The Cu-alloy layer may further contain at least one metal selected from aluminum (Al), gold (Au), nickel (Ni), cobalt (Co), silicon (Si), titanium (Ti), and tantalum (Ta). These additional metals are preferably contained 0.1 to 3 wt % in the Cu-alloy layer.

The Cu-alloy layer is photo-etched to form a plurality of gate lines 121, second gate electrodes 124b, and storage electrodes 133 with an etchant. In one embodiment, the etchant may comprise hydrogen peroxide (H₂O₂), while in another embodiment the etchant may comprise a common etchant containing 50 to 80 wt % of phosphoric acid (H₂PO₃), 2 to 10 wt % of nitric acid (HNO₃), 2 to 15 wt % of acetic acid (CH₃COOH), and deionized water for the residue.

Referring to FIGS. 12-13B, after sequential deposition of a gate insulating layer 140, an intrinsic a-Si layer, and an extrinsic a-Si layer, the extrinsic a-Si layer and the intrinsic a-Si layer are photo-etched to form a plurality of extrinsic semiconductor stripes 164 and a plurality of intrinsic semiconductor stripes 151 and islands 154b including projections 154a on the gate insulating layer 140. The gate insulating layer 140 preferably comprises silicon nitride with a thickness of about 2,000Å to about 5,000Å, and the deposition temperature is preferably in a range of about 250-500° C.

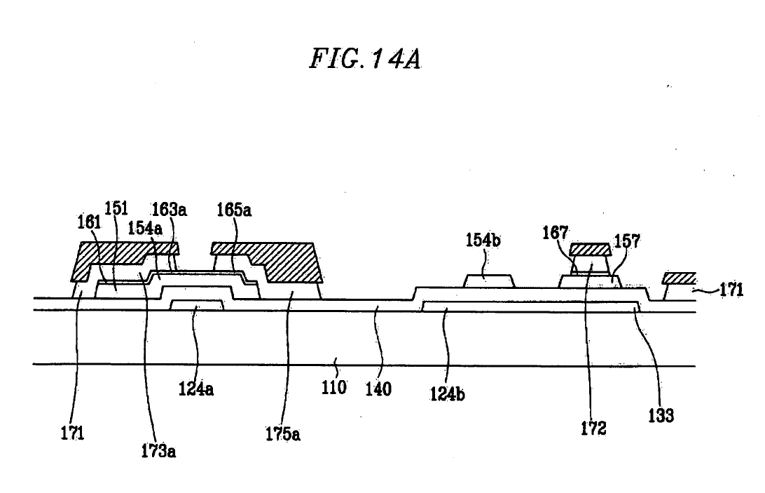

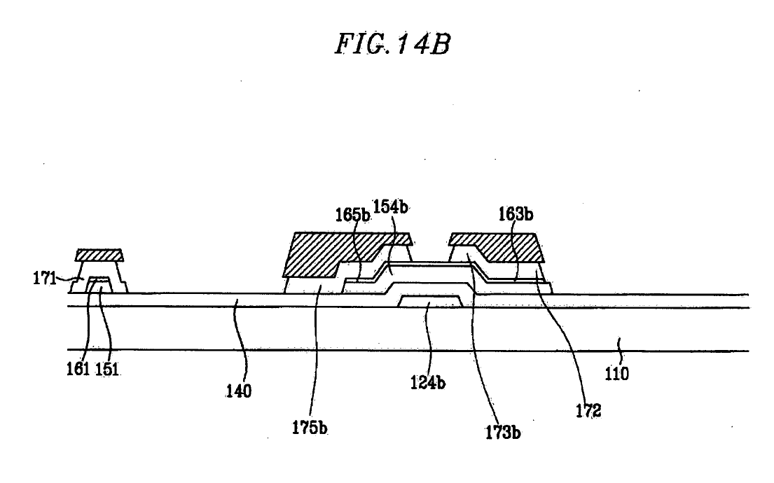

Next, referring to FIGS. 14A and 14B, a Cu-alloy layer is formed on the extrinsic semiconductor stripes 161. The Cu-alloy layer contains Cu as a main element and at least one selected from among molybdenum (Mo), tungsten (W), and chromium (Cr). The Cu-alloy layer is preferably formed to have thickness of about 3,000 Å, and the deposition temperature is preferably about 150° C.

Then, photoresist is coated on the Cu-alloy layer and is illuminated with a light through a photo-mask. Next, the illuminated photoresist is developed to form a photoresist pattern.

The Cu-alloy layer is etched with an etchant using the photoresist pattern. In some embodiments, the etchant may comprise hydrogen peroxide (H₂O₂). In other embodiments, the etchant may comprise a common etchant containing 50 to 80 wt % of phosphoric acid (H₂PO₃), 2 to 10 wt % of nitric acid (HNO₃), 2 to 15 wt % of acetic acid (CH₃COOH), and deionized water for the residue.

Through the above described processes, a plurality of data lines 171 having a plurality of first source electrode 173a, a plurality of first and second drain electrodes 175a and 175b, and a plurality of voltage transmission lines 172 having second source electrodes 173b are formed.

Before removing the photoresist pattern, portions of the extrinsic semiconductor stripes 164 which are not covered with the photoresist pattern are removed by dry etching. This completes a plurality of ohmic contact stripes 161 including projections 163a and a plurality of ohmic contact islands 163b, 165a, and 165b, and exposes portions of the intrinsic semiconductor stripes 151 and islands 154b.

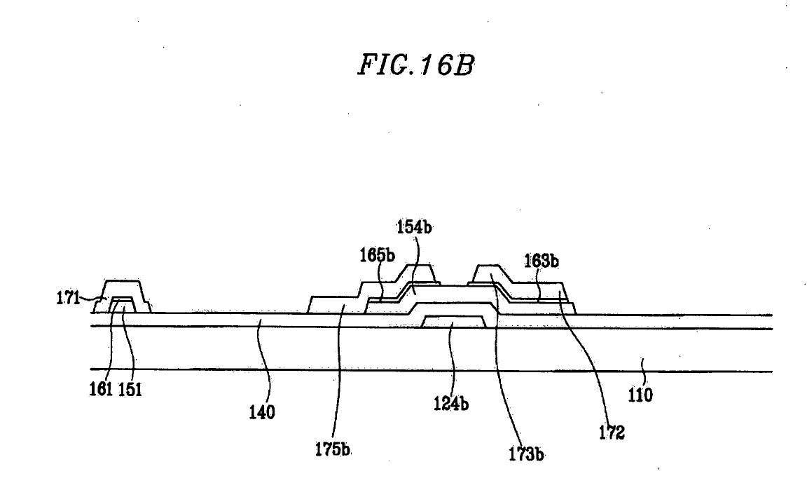

Since the extrinsic semiconductor stripes 164 are dry-etched using the photoresist pattern that was formed for forming the data conductors 171, 172, 175a, and 175b, referring to FIGS. 16A and 16B, the ohmic contacts 163a, 165a, 163b, and 165b have exposed portions outside of the source electrodes 173a and 173b and the drain electrodes 175a and 175b on the channel region. Furthermore, since the data conductors 171, 172, 175a, and 175b are covered by the photoresist pattern while etching the extrinsic semiconductor stripes 164, the data conductors 171, 172, 175a, and 175b (which comprise a Cu-alloy) do not contact the etching gas such as chlorine gas (Cl₂).

Oxygen plasma treatment may follow thereafter in order to stabilize the exposed surfaces of the semiconductor stripes 151.

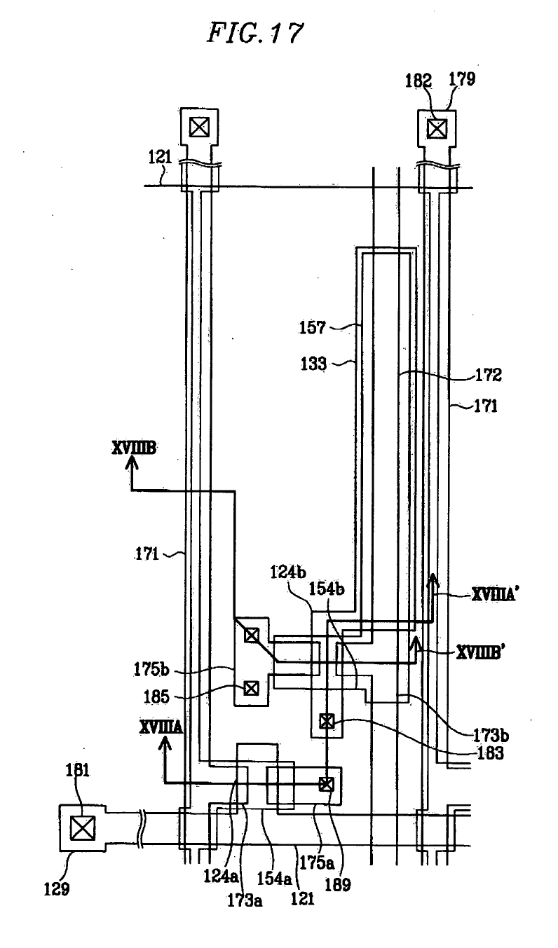

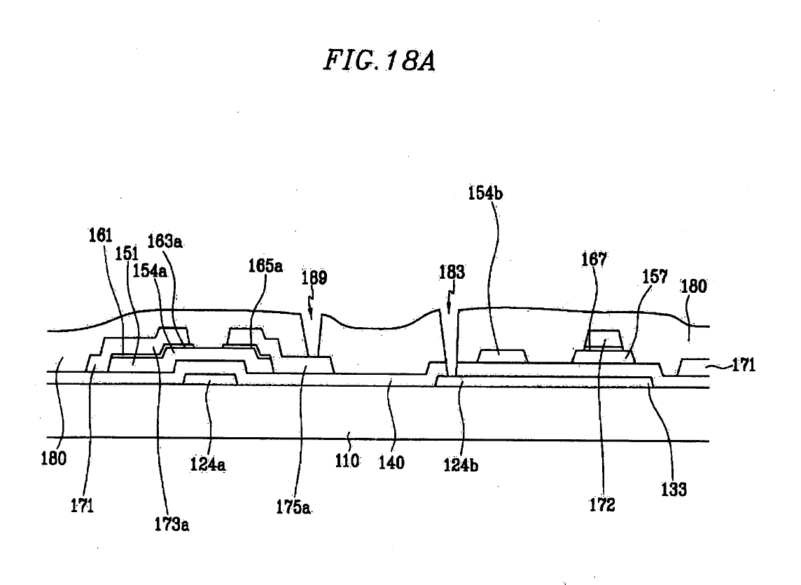

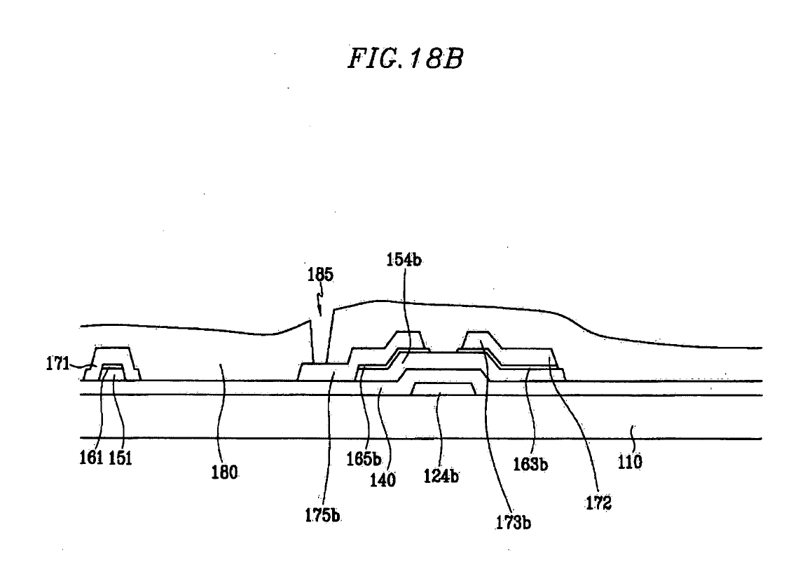

Referring to FIGS. 17 to 18B, a passivation layer 180 is formed of an organic insulating material or an inorganic insulating material.

The passivation layer 180 is patterned to form a plurality of contact holes 189, 185, 183, 181, and 182 exposing the first and second drain electrodes 175a and 175b, the second gate electrodes 124b, an end portion 129 of the gate line 121, and an end portion 179 of the data line 171.

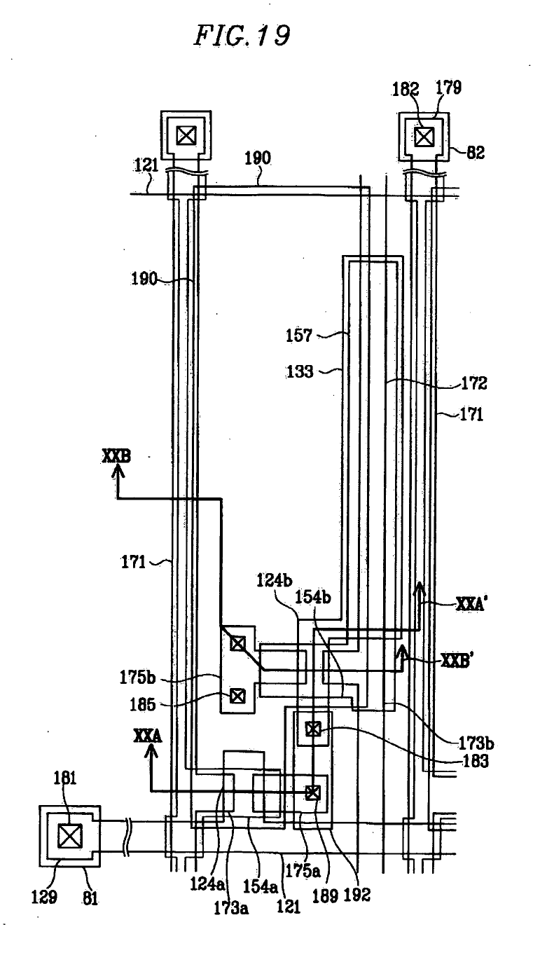

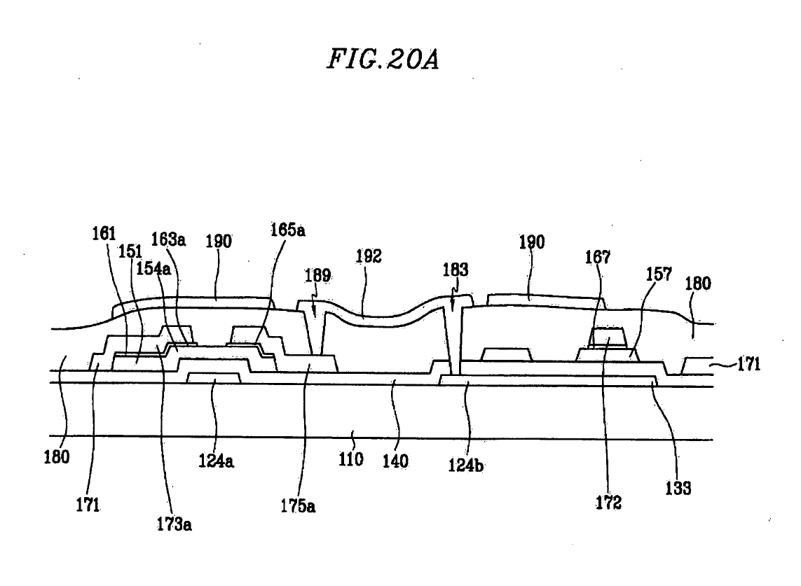

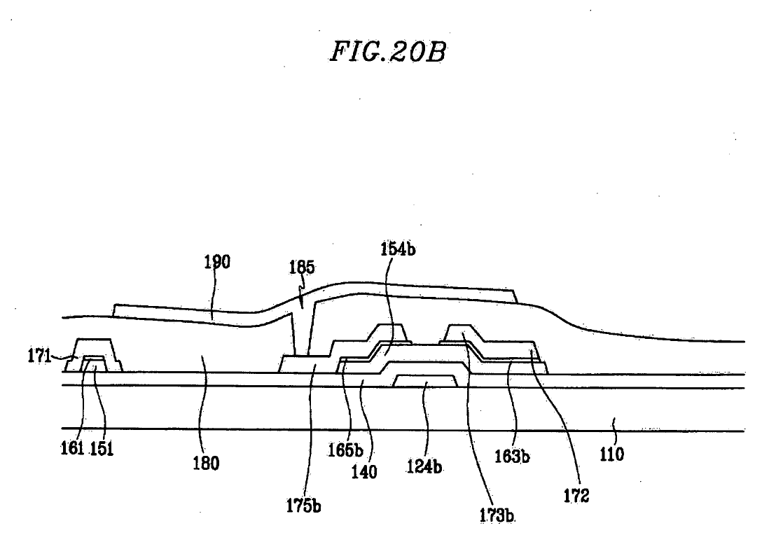

Referring to FIGS. 19 to 20B, a plurality of pixel electrodes 190, a plurality of connecting members 192, and contact assistants 81 and 82 are formed on the passivation layer 180 with a transparent conducting material such as ITO or IZO.

Referring to FIGS. 21 to 22B, a partition 803 and an auxiliary electrode 272 are formed by using a single photolithography step.

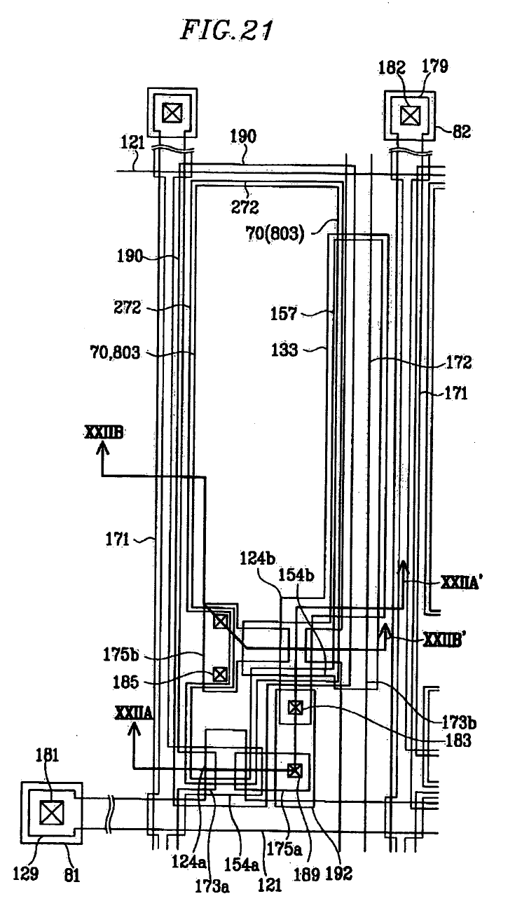

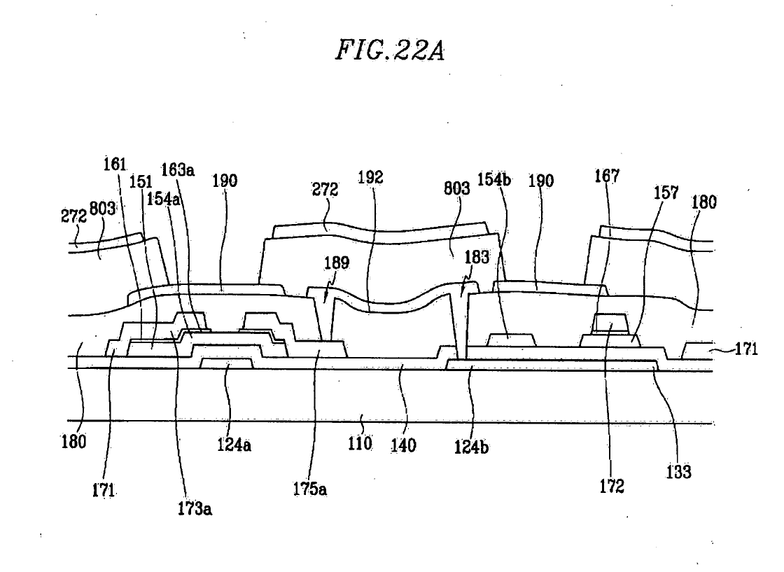

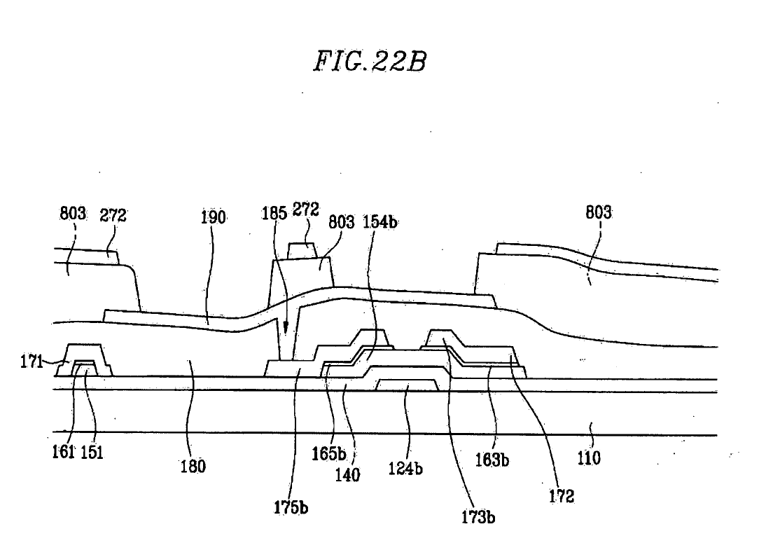

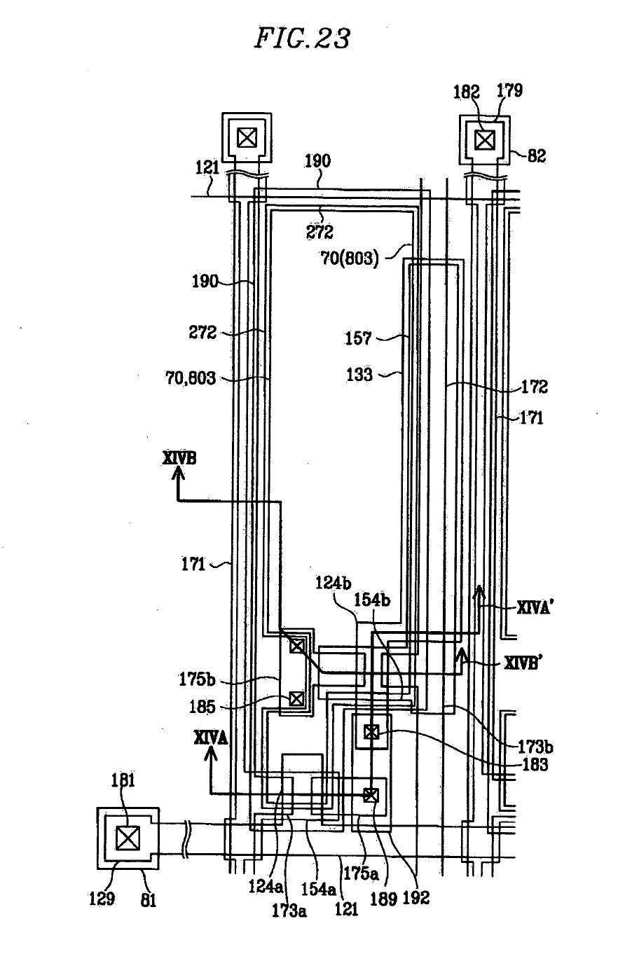

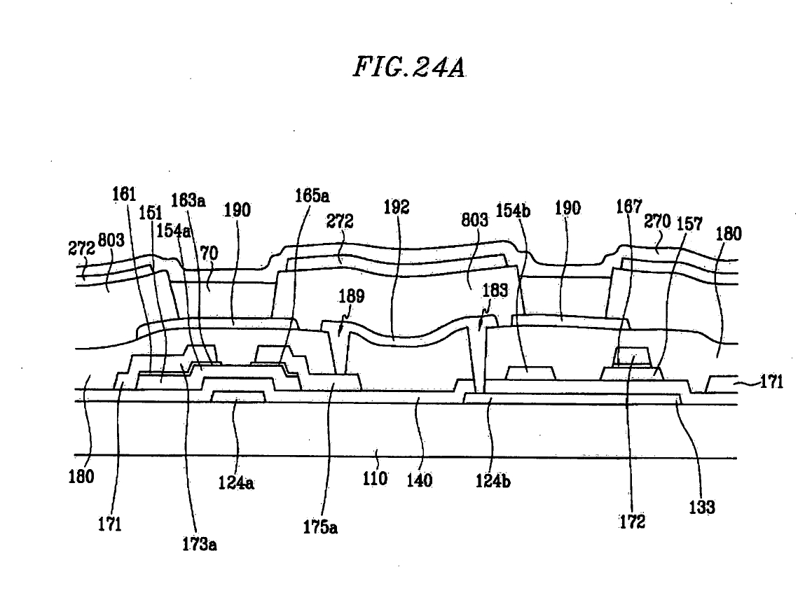

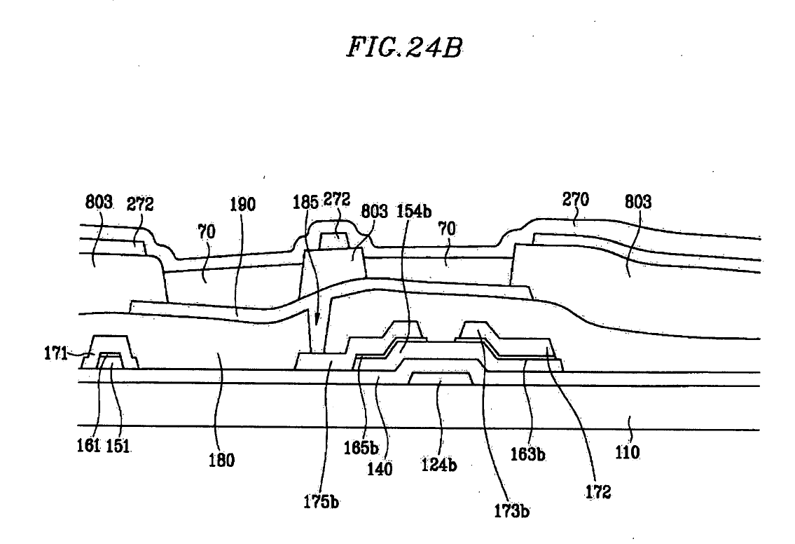

Finally, a plurality of organic light emitting members 70, preferably including multiple layers, are formed in the openings by deposition or inkjet printing following a masking step, and a common electrode 270 is subsequently formed as shown in FIGS. 23-24B.

In the present invention, since signal lines are formed of a Cu-alloy containing at least one of Mo, W, and Cr. The resulting signal lines have low resistivity and good reliability.

Although preferred embodiments of the present invention have been described in detail hereinabove, it should be clearly understood that many variations and/or modifications of the basic inventive concepts herein taught, which may appear to those skilled in the present art, will still fall within the spirit and scope of the present invention, as defined in the appended claims.

What is claimed is:

1. A signal line comprising a Cu-alloy including
copper (Cu) and at least one metal selected from the group consisting of molybdenum (Mo), tungsten (W), and chromium (Cr).

2. The signal line of claim 1, wherein the at least one metal selected from the group consisting of molybdenum (Mo), tungsten (W), and chromium (Cr) is contained 0.1 to 3 wt % in the Cu-alloy.

3. The signal line of claim 1, further comprising at least one metal selected from the group consisting of aluminum (Al), gold (Au), nickel (Ni), cobalt (Co), silicon (Si), titanium (Ti), and tantalum (Ta).

4. A thin film transistor array panel comprising:
an insulating substrate;
a gate line formed on the insulating substrate, the gate line configured to provide a gate signal;
a data line configured to provide a data signal indicative of a desired image part;
a thin film transistor connected to the gate line and the data line; and
a pixel electrode connected to the thin film transistor,
wherein at least one of the gate line and the data line comprises a Cu-alloy including Cu and at least one metal selected from the group consisting of molybdenum (Mo), tungsten (W), and chromium (Cr).

5. The thin film transistor array panel of claim 4, wherein the at least one metal selected from the group consisting of molybdenum (Mo), tungsten (W), and chromium (Cr) is contained 0.1 to 3 wt % in the Cu-alloy.

6. The thin film transistor array panel of claim 4, wherein the Cu-alloy further includes at least one metal selected from the group consisting of aluminum (Al), gold (Au), nickel (Ni), cobalt (Co), silicon (Si), titanium (Ti), and tantalum (Ta).

7. The thin film transistor array panel of claim 6, wherein the at least one metal selected from the group consisting of aluminum (Al), gold (Au), nickel (Ni), cobalt (Co), silicon (Si), titanium (Ti), and tantalum (Ta) is contained 0.1 to 3 wt % in the Cu-alloy.

8. A thin film transistor array panel comprising:
an insulating substrate;
a gate line formed on the insulating substrate;
a gate insulating layer formed on the gate line;
a semiconductor layer formed on the gate insulating layer;
ohmic contacts formed on the gate insulating layer and the semiconductor layer;
a data line having a source electrode formed on one of the ohmic contacts and having a narrower width than the ohmic contact thereunder;
a drain electrode formed on one of the ohmic contacts and facing the source electrode, the drain electrode having a narrower width than the ohmic contact thereunder, wherein the source electrode and the drain electrode are separated by a gap; and
a pixel electrode connected to the drain electrode,
wherein at least one of the gate line and the data line comprises a Cu-alloy comprising Cu and at least one metal selected from the group consisting of molybdenum (Mo), tungsten (W), and chromium (Cr).

9. The thin film transistor array panel of claim 8, wherein the at least one metal selected from the group consisting of molybdenum (Mo), tungsten (W), and chromium (Cr) is contained 0.1 to 3 wt % in the Cu-alloy.

10. The thin film transistor array panel of claim 8, wherein the Cu-alloy further contain at least one metal selected from the group consisting of aluminum (Al), gold (Au), nickel (Ni), cobalt (Co), silicon (Si), titanium (Ti), and tantalum (Ta).

11. The thin film transistor array panel of claim 10, wherein the at least one metal selected from the group consisting of aluminum (Al), gold (Au), nickel (Ni), cobalt (Co), silicon (Si), titanium (Ti), and tantalum (Ta) is contained 0.1 to 3 wt % in the Cu-alloy.

12. A manufacturing method of a thin film transistor array panel comprising:
forming a gate line having a gate electrode on an insulating substrate;
depositing a gate insulating layer, a semiconductor layer, and an ohmic contact layer on the gate line;
patterning the ohmic contact layer and the semiconductor layer to form an ohmic contact pattern and a semiconductor pattern;
depositing a Cu-alloy layer comprising Cu and at least one selected from the group consisting of molybdenum (Mo), tungsten (W), and chromium (Cr);
forming a photoresist pattern on the Cu-alloy layer;
forming a drain electrode and a data line having a source electrode by etching the Cu-alloy layer using the photoresist pattern;
etching the ohmic contact pattern using the photoresist pattern; and
forming a pixel electrode connected to the drain electrode.

13. The method of claim 12, wherein the gate line comprises a Cu-alloy layer comprising Cu and at least one selected from the group consisting of molybdenum (Mo), tungsten (W), and chromium (Cr).

14. The method of claim 13, wherein the at least one metal selected from the group consisting of molybdenum (so), tungsten (W), and chromium (Cr) is contained 0.1 to 3 wt % in the Cu-alloy.

15. The method of claim 12, wherein the at least one metal selected from the group consisting of molybdenum (No), tungsten (W), and chromium (Cr) is contained 0.1 to 3 wt % in the Cu-alloy.
